(19) United States
(12) Patent Application Publication
(10) Pub. No.: US 2026/0033117 A1
(43) Pub. Date: Jan. 29, 2026

(54) COMPOSITE TRANSPORT LAYERS, PEROVSKITE SOLAR CELLS, AND METHODS FOR PREPARATION THEREOF

(71) Applicant: HANGZHOU MICROQUANTA SEMICONDUCTOR CORPORATION LIMITED, Hangzhou (CN)

(72) Inventors: Buyi YAN, Hangzhou (CN); Jizhong YAO, Hangzhou (CN); Nannan GU, Hangzhou (CN)

(73) Assignee: HANGZHOU MICROQUANTA SEMICONDUCTOR CORPORATION LIMITED, Hangzhou (CN)

(21) Appl. No.: 19/342,654

(22) Filed: Sep. 28, 2025

Related U.S. Application Data
(63) Continuation of application No. PCT/CN2023/109241, filed on Jul. 26, 2023.

(30) Foreign Application Priority Data
Jun. 14, 2023 (CN) 202310711396.X

(51) Int. Cl. H10K 30/40; H10K 30/86; H10K 71/12

(52) U.S. Cl. CPC H10K 30/40; H10K 30/86; H10K 71/12

(57) ABSTRACT

Disclosed relates to a composite transport layer, a perovskite solar cell, and a method for preparation thereof. The composite transport layer comprises a transition layer, a hole transport layer, and a buffer layer sequentially stacked along a light incident direction. A preparation material of the transition layer is NiₓA_{y}Si_{z}SnₘOₙ or CuₓA_{y}Si_{z}SnₘOₙ, x>0, y≥0, z≥0, m≥0, n>0, A is aluminum (Al) or boron (B), and the preparation material of the transition layer at least includes any one of A, silicon (Si), or tin (Sn); a preparation material of the hole transport layer is any one of NiOₓ, CuₓO, or CuSCN; and a preparation material of the buffer layer is NiₐE_{b}N_{c}O_{d} or CuₐE_{b}N_{c}O_{d}, a>0, b≥0, c>0, d≥0, and E is any one of Al, B, Si, zinc (Zn), cobalt (Co), or zirconium (Zr).

### CROSS REFERENCE TO RELATED APPLICATIONS

The present disclosure is a continuation of International Patent Application No. PCT/CN2023/109241, filed on Jul. 26, 2023, which claims priority to Chinese Patent Application No. 202310711396.X, filed on Jun. 14, 2023, the entire contents of each of which are incorporated herein by reference.

### TECHNICAL FIELD

The present disclosure belongs to a technical field of preparation of a perovskite solar cell, and in particular, to a composite transport layer, a perovskite solar cell, and a method for preparation thereof.

### BACKGROUND

Perovskite solar cells typically adopt either a conventional N-I-P device structure or an inverted P-I-N device structure. The conventional device at least includes, in sequence from a light incident surface: a transparent conductive layer, an electron transport layer (ETL), a perovskite active layer, a hole transport layer (HTL), and a back electrode. In contrast, the inverted device includes, in sequence from a light incident surface: a transparent conductive layer, a hole transport layer, a perovskite active layer, an electron transport layer, and a back electrode. Compared with the conventional device, the inverted device does not require the use of TiO₂, which exhibits high photocatalytic activity, or expensive hole transport materials such as Spiro-OMeTAD, which can be fabricated at low temperatures, with a simpler process and better stability. Nevertheless, currently, the high power conversion efficiencies are mostly achieved by conventional devices, with the highest efficiency reaching 26%, while the efficiencies of inverted devices are mostly in a range of 22% to 24%. Further optimization of the hole transport layer and interface in inverted devices is critical to improving the power conversion efficiency.

The relatively low power conversion efficiency of inverted devices is mainly due to the energy band mismatch at a first interface between the transparent conductive layer and the hole transport layer, and the numerous interfacial defects at a second interface between the hole transport layer and the perovskite active layer. The preparation materials of the hole transport layer are generally divided into three categories: 1) inorganic oxides or inorganic salts, 2) organic polymers, and 3) organic small molecules. Typical options for the first category of inorganic oxides or inorganic salts include NiOₓ, V₂O₅, CuO, and CuSCN; typical options for the second category of organic polymers include P3HT and PTAA; and typical options for the third category of organic small molecules include spiro-OMeTAD and self-assembled monolayer materials such as PACZ. Materials of the first category are easy to obtain and low-cost; however, their good hole transport performance arises from intrinsic defects in the materials. Typically, a higher defect density is required to achieve better hole transport performance, but such a high defect density tends to degrade the photo-thermal stability at the second interface between the hole transport layer and the perovskite active layer. As a result, it is difficult to simultaneously achieve both high power conversion efficiency and good stability. Taking NiOₓ as an example, to improve its hole mobility, it is necessary to increase the concentration of under-coordinated Ni³⁺ ions. However, a high concentration of Ni³⁺ also serves as the source that promotes photocatalytic reactions at the interface between NiOₓ and the perovskite active layer. Materials of the second category generally require longer synthesis routes and exhibit better hole transport performance, making it easier to achieve high-efficiency inverted devices. However, their main drawback lies in the poor photostability of the polymer materials themselves, which tend to decompose under prolonged outdoor illumination, resulting in rapid performance degradation of the inverted devices. Materials of the third category can further improve the power conversion efficiency of inverted devices based on the material of the second category. However, similar to the materials of the second category, due to the use of organic components, their stability under prolonged illumination is poor. To address these issues, there have also been reports of using composite structures combining inorganic and organic hole transport layers, or employing methods to passivate the inorganic hole transport layers. However, using a composite structure of inorganic and organic hole transport layers is merely a palliative solution, as the organic layer still decomposes under prolonged illumination, ultimately negating the effect of the composite structure. Passivating the inorganic hole transport layer, also considered a temporary compromise, often improves stability at the cost of reduced power conversion efficiency.

Besides, existing materials for preparing the hole transport layer are generally inorganic oxides. The hole transport layer of inorganic oxides presents the following issues: the structure formed by inorganic oxides may be overly dense, leading to difficulties in hole transport; inorganic nanocrystals are prone to aggregation during long-term operation due to charge imbalance caused by surface defects, which compromises material stability once aggregation occurs; and the surface of the inorganic interface contains numerous disordered dangling bonds, some of which may react with the perovskite material.

In summary, existing hole transport layers do not enable perovskite solar cells to combine high power conversion efficiencies with good stability.

### SUMMARY

The technical problem to be solved in the present disclosure is to provide a composite transport layer, a perovskite solar cell, and a method for preparation thereof. Oₙ the one hand, a composite structure is used for a hole transport layer, in which a transition layer and a buffer layer are arranged on an upper surface and lower surface of the hole transport layer, respectively. Such a configuration retains the high defect density and high hole mobility of the hole transport material, significantly improving the light stability and the power conversion efficiency of the perovskite solar cell. Oₙ the other hand, a coupling agent is doped into a preparation material of the composite transport layer, thereby improving the conductivity and stability of the hole transport layer made from inorganic oxide materials. As a result, the prepared perovskite solar cell achieves both high power conversion efficiency and good stability.

One or more embodiments of the present disclosure provide a first type of composite transport layer, comprising a transition layer, a hole transport layer, and a buffer layer sequentially stacked along a light incident direction. A preparation material of the transition layer is NiₓA_{y}Si_{z}SnₘOₙ or CuₓA_{y}Si_{z}SnₘOₙ, x>0, y≥0, z≥0, m≥0, n>0, A is aluminum (Al) or boron (B), and the preparation material of the transition layer at least includes any one of A, silicon (Si), or tin (Sn). A preparation material of the hole transport layer is any one of NiOₓ, CuₓO, or CuSCN. A preparation material of the buffer layer is NiₐE_{b}N_{c}O_{d} or CuₐE_{b}N_{c}O_{d}, a>0, b≥0, c>0, d≥0, and E is any one of Al, B, Si, zinc (Zn), cobalt (Co), or zirconium (Zr).

One or more embodiments of the present disclosure further provide a second type of composite transport layer, comprising a transition layer, a hole transport layer, and a buffer layer sequentially stacked along a light incident direction. A preparation material of the transition layer is NiₓA_{y}Si_{z}SnₘOₙ or CuₓA_{y}Si_{z}SnₘOₙ, x>0, y≥0, z≥0, m≥0, n>0, A is aluminum (Al) or boron (B), and the preparation material of the transition layer at least includes any one of A, Si, or Sn. A preparation material of the hole transport layer is any one of NiOₓ, CuₓO, or CuSCN. A preparation material of the buffer layer is NiₐE_{b}N_{c}O_{d} or CuₐE_{b}N_{c}O_{d}, a>0, b≥0, c>0, d≥0, and E is any one of Al, B, Si, Zn, Co, or Zr. The preparation material of the transition layer and/or the buffer layer is doped with a coupling agent to obtain a corresponding array transition layer and/or array buffer layer containing the coupling agent, a thin film prepared from the array transition layer and/or the array buffer layer doped with the coupling agent includes a plurality of array molecular groups containing the coupling agent that are discretely arranged and a plurality of openings separating two adjacent array molecular groups among the plurality of array molecular groups, and each of the plurality of opening communicates an upper surface and lower surface of the thin film in which it is located, respectively. The coupling agent is any one of a silane coupling agent, a titanate coupling agent, an aluminate coupling agent, a phosphate coupling agent, or a borate coupling agent.

One or more embodiments of the present disclosure further provide a first type of perovskite solar cell. An internal structure of the perovskite solar cell comprises a transparent conductive layer, a perovskite light-absorbing layer, an electron transport layer, and a back electrode stacked sequentially. The composite transport layer is arranged between the transparent conductive layer and the perovskite light-absorbing layer, a transition layer of the composite transport layer is in conformal contact with the transparent conductive layer, and a buffer layer of the composite transport layer is in conformal contact with the perovskite light-absorbing layer.

One or more embodiments of the present specification further provide a second type of perovskite solar cell. An internal structure of the perovskite solar cell comprises a transparent conductive layer, a perovskite light-absorbing layer, an electron transport layer, and a back electrode stacked sequentially. The composite transport layer is arranged between the transparent conductive layer and the perovskite light-absorbing layer, a transition layer of the composite transport layer is in conformal contact with the transparent conductive layer, and a buffer layer of the composite transport layer is in conformal contact with the perovskite light-absorbing layer.

### BRIEF DESCRIPTION OF THE DRAWINGS

The present disclosure will be further illustrated by way of exemplary embodiments, which will be described in detail by means of the accompanying drawings. These embodiments are not limiting, and in these embodiments, the same numbering denotes the same structure, where:

FIG. 1 is a schematic diagram illustrating an exemplary plan view of an internal structure of a first type of perovskite solar cell according to some embodiments of the present disclosure;

FIG. 2 is a schematic diagram illustrating an exemplary plan view of a first internal structure of a second type of perovskite solar cell according to some embodiments of the present disclosure;

FIG. 3 is a schematic diagram illustrating an exemplary plan view of a second internal structure of a second type of perovskite solar cell according to some embodiments of the present disclosure;

FIG. 4 is a schematic diagram illustrating an exemplary plan view of a third internal structure of a second type of perovskite solar cell according to some embodiments of the present disclosure;

FIG. 5 is a schematic diagram illustrating a comparison of power conversion efficiency curves of a perovskite solar cell prepared in Embodiment 1 and a perovskite solar cell prepared in Comparative Example 1;

FIG. 6 is a schematic diagram illustrating a comparison of power conversion efficiency curves of a perovskite solar cell prepared in Embodiment 1 and perovskite solar cells prepared in Comparative Examples 1 and 2;

FIG. 7 is a schematic diagram illustrating a comparison of aging experiment curves of a perovskite solar cell prepared in Embodiment 1 and perovskite solar cells prepared in Comparative Examples 1, 2, and 3;

FIG. 8 is a schematic diagram illustrating an exemplary three-dimensional structure of a composite transport layer of the second internal structure of the second type of perovskite solar cell in FIG. 3;

FIG. 9 is a schematic diagram illustrating a comparison of power conversion efficiency curves of a perovskite solar cell prepared in Embodiment 5 and perovskite solar cells prepared in Comparative Examples 1, 3, and 4; and

FIG. 10 is a schematic diagram illustrating a comparison of aging experiment curves of a perovskite solar cell prepared in Embodiment 5 and perovskite solar cells prepared in Comparative Embodiments 1, 3, and 4.

### DETAILED DESCRIPTION

To make the technical problem to be solved, the technical solution, and the beneficial effect of the present disclosure clearer and more understandable, the present disclosure is described in further detail below in conjunction with the accompanying drawings and embodiments. It should be understood that the specific embodiments described herein are only for explaining the present disclosure, and are not intended to limit the present disclosure.

Perovskite solar cells are a new type of power generator that provides clean electricity by converting light energy into electricity through the photovoltaic effect. Compared to traditional silicon-based solar cells, perovskite solar cells are cheaper to manufacture and more environmentally friendly.

A hole transport layer is a functional structural layer in the perovskite solar cell. When sunlight hits a perovskite solar cell, electron-hole pairs are generated, and the hole transport layer is mainly responsible for transporting the holes generated after light exposure to the electrodes while preventing the reverse flow of electrons, thereby increasing the photoelectric power conversion efficiency of the cell.

To further enhance the photovoltaic power generation efficiency, it is necessary to provide a new type of perovskite solar cell comprising a composite transport layer to balance both high power conversion efficiency and good stability.

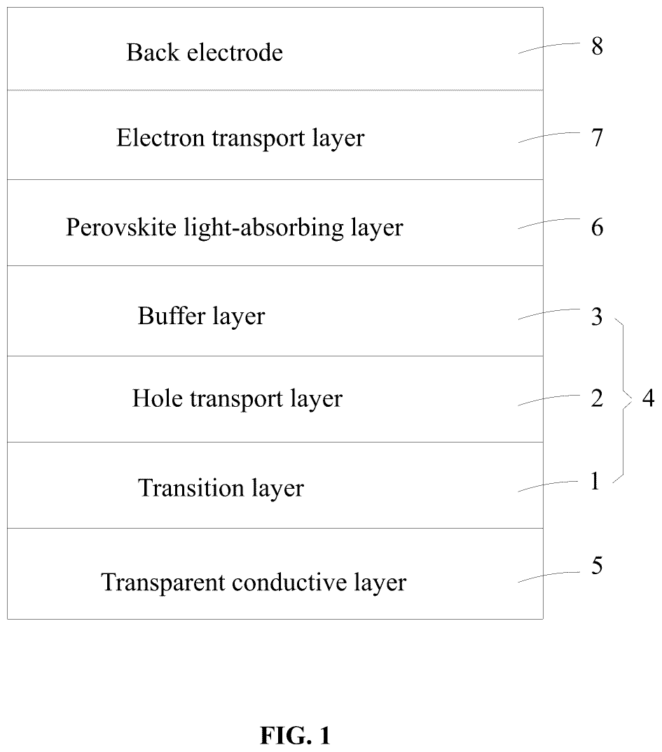

FIG. 1 is a schematic diagram illustrating an exemplary plan view of an internal structure of a first type of perovskite solar cell according to some embodiments of the present disclosure. As shown in FIG. 1, a first type of composite transport layer may include a transition layer 1, a hole transport layer 2, and a buffer layer 3 sequentially stacked along a light incident direction. A preparation material of the transition layer 1 may be NiₓA_{y}Si_{z}SnₘOₙ or CuₓA_{y}Si_{z}SnₘOₙ, x>0, y≥0, z≥0, m≥0, and n>0, A may be aluminum (Al) or boron (B), and the preparation material of the transition layer 1 may at least include any one of A, silicon (Si), or tin (Sn), i.e., the preparation material of the transition layer 1 may be nickel oxide or copper oxide containing at least one of Si, Sn, and A. A preparation material of the hole transport layer 2 may be any one of nickel oxide (NiOₓ), copper oxide (CuₓO), or cuprous thiocyanate (CuSCN). A preparation material of the buffer layer 3 may be NiₐE_{b}N_{c}O_{d} or CuₐE_{b}N_{c}O_{d}, a>0, b≥0, c>0, d≥0, and E may be any one of Al, B, Si, zinc (Zn), cobalt (Co), or zirconium (Zr), i.e., the preparation material of the buffer layer 3 may be nickel nitride, nickel oxynitride, copper nitride, or copper oxynitride containing any one of Al, B, Si, Zn, Co, and Zr.

The composite transport layer refers to a composite layer that transfers holes in electron-hole pairs to a transparent conductive layer 5. In some embodiments, the composite transport layer includes the transition layer 1, the hole transport layer 2, and the buffer layer 3 sequentially stacked along the light incident direction. A detailed description of the transparent conductive layer 5 can be found in the descriptions below.

The transition layer 1 refers to a functional structural layer located on a surface of the composite transport layer. The transition layer 1 may establish a doping concentration gradient and energy-level alignment between the transparent conductive layer and the hole transport layer, thereby enhancing the photostability of the perovskite solar cell.

In some embodiments, the preparation material of the transition layer 1 may be NiₓA_{y}Si_{z}SnₘOₙ or CuₓA_{y}Si_{z}SnₘOₙ, x>0, y≥0, z≥0, m≥0, n>0, and A may be Al or B. The preparation material of the transition layer 1 may at least include any one of A, Si, or Sn.

The hole transport layer 2 refers to an intermediate layer within the composite transport layer, and the hole transport layer 2 may transport photo-generated holes to the electrode while blocking the reverse flow of electrons.

In some embodiments, the preparation material of the hole transport layer 2 may be any one of NiOₓ, CuₓO, or CuSCN.

The buffer layer 3 refers to a functional structural layer on the surface of the composite transport layer. The buffer layer 3 may passivate surface defects of the hole transport layer 2 and reduce non-radiative recombination at an interface between a perovskite light-absorbing layer 6 and the hole transport layer 2.

In some embodiments, the preparation material of the buffer layer 3 may be NiₐE_{b}N_{c}O_{d} or CuₐE_{b}N_{c}O_{d}, a>0, b≥0, c>0, d≥0, and E may be any one of Al, B, Si, Zn, Co, or Zr.

In some embodiments of the present disclosure, in the first type of composite transport layer of the present disclosure, a hole transport layer may adopt a composite structure, with a transition layer and a buffer layer disposed on an upper surface and lower surface of the hole transport layer, respectively. Such a configuration retains the high defect density and high hole mobility of a hole transport material, enabling a perovskite solar cell incorporating the composite transport layer to achieve both high power conversion efficiency and long-term photo-thermal stability.

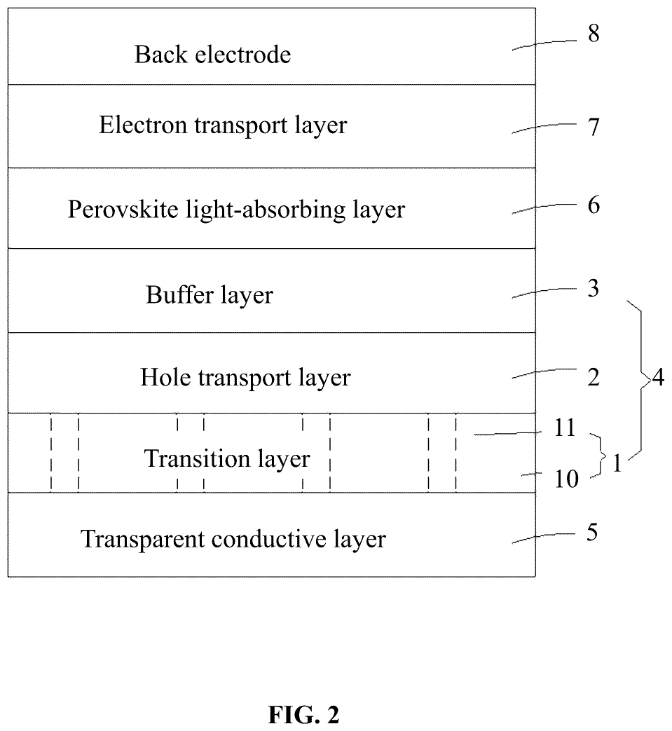

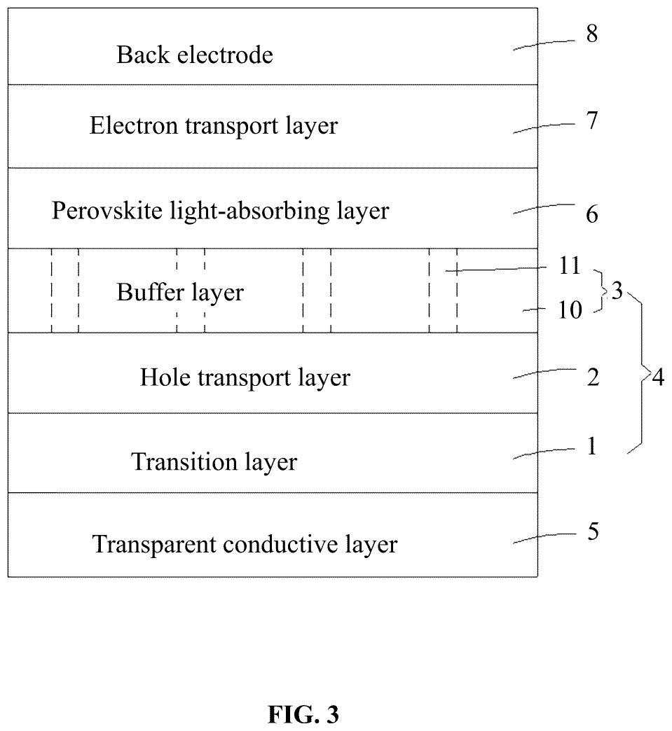

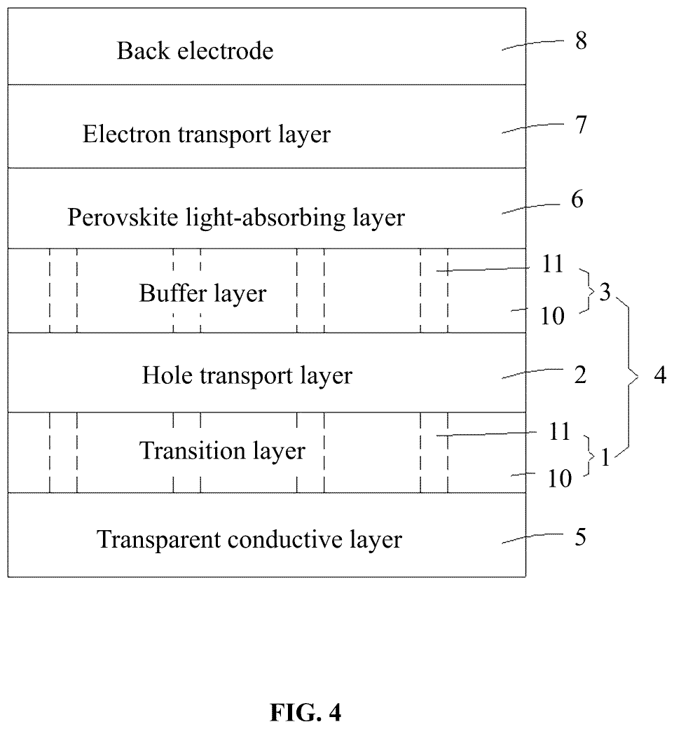

FIG. 2 is a schematic diagram illustrating an exemplary plan view of a first internal structure of a second type of perovskite solar cell according to embodiments of the present disclosure; FIG. 3 is a schematic diagram illustrating an exemplary plan view of a second internal structure of a second type of perovskite solar cell according to embodiments of the present disclosure; and FIG. 4 is a schematic diagram illustrating an exemplary plan view of a third internal structure of a second type of perovskite solar cell according to embodiments of the present disclosure.

As shown in FIG. 2 to FIG. 4, a second type of composite transport layer may include the transition layer 1, the hole transport layer 2, and the buffer layer 3 stacked sequentially along a light incident direction. A preparation material of the transition layer 1 may be NiₓA_{y}Si_{z}SnₘOₙ or NiₓA_{y}Si_{z}SnₘOₙ, x>0, y≥0, z≥0, m≥0, and n>0, and A may be Al or B, and the preparation material of the transition layer 1 may at least include any one of A, Si, or Sn. A preparation material of the hole transport layer 2 may be any one of NiOₓ, CuₓO, or CuSCN. A preparation material of the buffer layer 3 may be NiₐE_{b}N_{c}O_{d} or CuₐE_{b}N_{c}O_{d}, a>0, b≥0, c>0, and d≥0, and E may be any one of Al, B, Si, Zn, Co, or Zr. In some embodiments, when the transition layer 1 is an array transition layer, a structure as shown in FIG. 2 is formed; when the buffer layer 3 is an array buffer layer, a structure as shown in FIG. 3 is formed; and when the transition layer 1 is an array transition layer and the buffer layer 3 is an array buffer layer, a structure as shown in FIG. 4 is formed.

The preparation material of the transition layer and/or the buffer layer may also be doped with a coupling agent to obtain a corresponding array transition layer and/or array buffer layer containing the coupling agent. A thin film prepared from the array transition layer and/or the array buffer layer doped with the coupling agent may include a plurality of array molecular groups containing the coupling agent that are discretely arranged and a plurality of openings separating two adjacent array molecular groups among the plurality of array molecular groups, and each of the plurality of opening communicates an upper surface and lower surface of the thin film in which it is located. The coupling agent may be any one of a silane coupling agent, a titanate coupling agent, an aluminate coupling agent, a phosphate coupling agent, or a borate coupling agent.

The transition layer 1, the hole transport layer 2, and the buffer layer 3 of the second type of composite transport layer are similar to the transition layer 1, the hole transport layer 2, and the buffer layer 3 of the first type of composite transport layer. A difference lies in that, in the second type of composite transport layer, the preparation material of the transition layer 1 and/or the buffer layer 3 may be doped with the coupling agent. More descriptions about the transition layer 1, the hole transport layer 2, and the buffer layer 3 can be found in the related description above.

The coupling agent refers to a chemical additive used for coupling modification. The coupling agent can prevent the aggregation of inorganic nanocrystals and passivate dangling bonds on the surfaces of the inorganic materials, thereby enhancing the service life and stability of the material.

In some embodiments, the coupling agent is any one of the silane coupling agent, the titanate coupling agent, the aluminate coupling agent, the phosphate coupling agent, or the borate coupling agent.

In some embodiments, an addition amount of the coupling agent and a concentration of a nanoparticle suspension are determined based on actual application scenarios and needs.

In some embodiments, the addition amount of the coupling agent is in a range of 0.5% to 5% of a volume of a corresponding nanoparticle suspension for preparing the transition layer 1 and/or the buffer layer 3, and a concentration of the nanoparticle suspension is in a range of 0.1 wt. % to 10 wt. %, where wt. % denotes a percentage of mass concentration.

In some embodiments, the addition amount of the coupling agent may also be in one of the following: a range of 0.5% to 2.0%, a range of 0.5% to 2.5%, a range of 0.5% to 3.0%, a range of 1.0% to 3.5%, a range of 1.0% to 4.0%, a range of 1.5% to 4.0%, a range of 2.0% to 4.5%, a range of 2.5% to 5.0%, a range of 3.0% to 5.0%, a range of 3.5% to 5.0%, or a range of 3.5% to 5.0% of the volume of the corresponding nanoparticle suspension for preparing the transition layer 1 and/or the buffer layer 3.

In some embodiments, the addition amount of the coupling agent may also be one of 0.5%, 1.0%, 1.5%, 2.0%, 2.5%, 2.5%, 3.0%, 3.5%, 4.0%, 4.5%, or 5.0% of the volume of the corresponding nanoparticle suspension for preparing the transition layer 1 and/or the buffer layer 3.

In some embodiments, the concentration of the nanoparticle suspension may also be in one of the following: a range of 0.1% to 4%, a range of 0.5% to 5%, a range of 1% to 6%, a range of 0.1% to 5%, a range of 2% to 7%, a range of 3% to 8%, a range of 0.1% to 6%, a range of 5% to 10%, a range of 0.5% to 7%, or a range of 2% to 10%.

In some embodiments, the concentration of the nanoparticle suspension may also be one of 0.1%, 0.5%, 1%, 2%, 3%, 4%, 5%, 6%, 7%, 8%, 9%, or 10%.

In some embodiments, the preparation material of the transition layer and/or the buffer layer is doped with the coupling agent to obtain a corresponding array transition layer and/or array buffer layer containing the coupling agent.

The array transition layer refers to the transition layer 1 having a three-dimensional structure on an outer surface, and the array buffer layer refers to the buffer layer 3 having a three-dimensional structure on an outer surface. FIG. 8 is a schematic diagram illustrating an exemplary three-dimensional structure of a composite transport layer of a second internal structure of a second type of perovskite solar cell in FIG. 3. As shown in FIG. 8, the array buffer layer 3 includes a plurality of array molecular groups 11 containing the coupling agent that are discretely arranged and a plurality of openings 10 disposed between two adjacent array molecular groups 11 among the plurality of array molecular groups 11.

In some embodiments, each of the openings 10 may communicate an upper surface and lower surface of the thin film in which it is located. In conjunction with FIG. 2 to FIG. 4, when the transition layer 1 is the array transition layer, the openings 10 may communicate the transparent conductive layer 5 with the hole transport layer 2; and when the buffer layer 3 is the array buffer layer, the openings 10 may communicate the perovskite light-absorbing layer 6 with the hole transport layer 2.

In some embodiments of the present disclosure, in the second type of composite transport layer, the hole transport layer adopts a composite array structure, and the preparation material of the transition layer and/or the buffer layer may be doped with the coupling agent to obtain the array transition layer and/or the array buffer layer, improving the conductivity and stability of the hole transport layer made of inorganic oxide materials. As a result, a perovskite solar cell comprising the second type of composite transport layer not only exhibits significantly enhanced photostability but also improved power conversion efficiency.

The opening 10 refers to a spacing region between two adjacent array molecular groups 11. The length of the opening may be determined according to actual application scenarios and needs.

In some embodiments, the length of the opening 10 is in a range of 10 nm to 200 nm.

In some embodiments, the length of the opening 10 may also be in one of the following: a range of 10 nm to 30 nm, a range of 30 nm to 50 nm, a range of 50 nm to 70 nm, a range of 70 nm to 90 nm, a range of 90 nm to 110 nm, a range of 110 nm to 130 nm, a range of 130 nm to 150 nm, a range of 150 nm to 170 nm, a range of 170 nm to 190 nm, or a range of 190 nm to 200 nm.

In some embodiments, the length of the opening 10 may also be one of 10 nm, 30 nm, 50 nm, 70 nm, 90 nm, 110 nm, 130 nm, 150 nm, 170 nm, or 190 nm.

In some embodiments, in the first type of composite transport layer and the second type of composite transport layer of the present disclosure, the thicknesses of the transition layer 1, the hole transport layer 2, and the buffer layer 3 may be determined according to actual application scenarios and needs.

In some embodiments, the thickness of the transition layer 1 is in a range of 0.2 nm to 30 nm, the thickness of the hole transport layer 2 is in a range of 1 nm to 100 nm, and the thickness of the buffer layer 3 is in a range of 0.2 nm to 50 nm.

In some embodiments, the thickness of the transition layer 1 may also be in one of the following: a range of 0.2 nm to 0.5 nm, a range of 0.2 nm to 1 nm, a range of 0.2 nm to 2 nm, a range of 0.2 nm to 5 nm, a range of 0.2 nm to 10 nm, a range of 0.5 nm to 5 nm, a range of 1 nm to 5 nm, a range of 5 nm to 10 nm, a range of 10 nm to 20 nm, or a range of 20 nm to 30 nm; the thickness of the hole transport layer 2 may also be in one of the following: a range of 1 nm to 5 nm, a range of 5 nm to 10 nm, a range of 10 nm to 20 nm, a range of 20 nm to 30 nm, a range of 30 nm to 50 nm, a range of 50 nm to 70 nm, a range of 70 nm to 80 nm, a range of 80 nm to 90 nm, a range of 90 nm to 100 nm, or a range of 1 nm to 100 nm; and the thickness of the buffer layer 3 may also be one of the following: a range of 0.2 nm to 0.5 nm, a range of 0.2 nm to 1 nm, a range of 0.2 nm to 5 nm, a range of 0.5 nm to 1 nm, a range of 1 nm to 5 nm, a range of 5 nm to 10 nm, a range of 10 nm to 20 nm, a range of 20 nm to 30 nm, a range of 30 nm to 40 nm, or a range of 40 nm to 50 nm.

In some embodiments, the thickness of the transition layer 1 may also be one of 0.2 nm, 0.5 nm, 1 nm, 2 nm, 5 nm, 10 nm, 15 nm, 20 nm, 25 nm, or 30 nm; the thickness of the hole transport layer 2 may also be one of 1 nm, 5 nm, 10 nm, 20 nm, 30 nm, 50 nm, 70 nm, 80 nm, 90 nm, or 100 nm; and the thickness of the buffer layer 3 may also be one of 0.2 nm, 0.5 nm, 1 nm, 5 nm, 10 nm, 20 nm, 30 nm, 40 nm, or 50 nm.

In some embodiments of the present disclosure, setting the addition amount of the coupling agent to be in a range of 0.5 to 5% of the volume of the corresponding nanoparticle suspension, the concentration of the nanoparticle suspension to be in a range of 0.1 wt. % to 10 wt. %, the length of the opening to be in a range of 10 nm to 200 nm, the thickness of the hole transport layer to be in a range of 1 nm to 100 nm, and the thickness of the buffer layer to be in a range of 0.2 nm to 50 nm can ensure the hole transport ability of the composite transport layer and greatly enhance the power conversion efficiency of the perovskite solar cell.

Referring to FIG. 1, the present disclosure provides a first type of perovskite solar cell, an internal structure of the perovskite solar cell comprises the transparent conductive layer 5, the perovskite light-absorbing layer 6, an electron transport layer 7, and a back electrode 8 stacked sequentially, and a first type of composite transport layer 4 may be disposed between the transparent conductive layer 5 and the perovskite light-absorbing layer 6. The transition layer 1 of the composite transport layer 4 may be in conformal contact with the transparent conductive layer 5, the buffer layer 3 of the composite transport layer 4 may be in conformal contact with the perovskite light-absorbing layer 6, and the hole transport layer 2 of the composite transport layer 6 may be disposed between the transition layer 1 and the buffer layer 3.

The transparent conductive layer 5 refers to the positive electrode of the perovskite solar cell. The transparent conductive layer 5 may typically be made of a transparent conductive material, which ensures that light can reach the perovskite light-absorbing layer 6 without obstruction, while also forming a portion of the external circuit in conjunction with the back electrode 8 to provide electrical output.

The perovskite light-absorbing layer 6 refers to a structural layer that absorbs light energy, and the perovskite light-absorbing layer 6 is capable of generating electron-hole pairs upon illumination, thereby enabling photoelectric conversion to produce electrical energy.

The electron transport layer 7 refers to a transport layer that transports electrons from the electron-hole pairs to the back electrode 8. The electron transport layer 7 and the hole transport layer 2 may cooperate with each other to transport the electrons and holes to the back electrode 8 and the transparent conductive layer 5, respectively, to generate electrical energy.

The back electrode 8 refers to the negative electrode of the perovskite solar cell, and the back electrode 8 may be made of a metallic material. The back electrode 8 and the transparent conductive layer 5 may serve as the electrodes of the perovskite solar cell, respectively, and may be used to transfer the electrical energy generated by the perovskite solar cell to the external circuit.

In some embodiments, as shown in FIG. 1, the first type of composite transport layer 4 is disposed between the transparent conductive layer 5 and the perovskite light-absorbing layer 6. The transition layer 1 of the composite transport layer 4 may be in conformal contact with the transparent conductive layer 5, the buffer layer 3 of the composite transport layer 4 may be in conformal contact with the perovskite light-absorbing layer 6, and the hole transport layer 2 of the composite transport layer 4 may be disposed between the transition layer 1 and the buffer layer 3. A detailed description of the first type of composite transport layer 4 can be found in the descriptions above.

Referring to FIG. 2 to FIG. 4, the present disclosure also provides a second type of perovskite solar cell, an internal structure of the perovskite solar cell comprises the transparent conductive layer 5, the perovskite light-absorbing layer 6, the electron transport layer 7, and the back electrode 8 stacked sequentially, and the second type of composite transport layer 4 may be disposed between the transparent conductive layer 5 and the perovskite light-absorbing layer 6. The transition layer 1 of the composite transport layer 4 may be in conformal contact with the transparent conductive layer 5, the buffer layer 3 of the composite transport layer 4 may be in conformal contact with the perovskite light-absorbing layer 6, and the hole transport layer 2 of the composite transport layer 4 may be disposed between the transition layer 1 and the buffer layer 3.

A detailed description of the transparent conductive layer 5, the perovskite light-absorbing layer 6, the electron transport layer 7, the back electrode 8, and the second composite transport layer 4 can be found in the descriptions above.

In the first type of perovskite solar cell and the second type of perovskite solar cell of the present disclosure, a molecular formula of a preparation material of the perovskite light-absorbing layer 6 may be ABX₃, where A may be at least one cation selected from cesium, rubidium, ammonium, formamidine, and alkali metal cations; B may be a divalent metal cation selected from any one of lead, tin, tungsten, copper, zinc, gallium, germanium, arsenic, selenium, rhodium, palladium, silver, cadmium, indium, antimony, osmium, iridium, platinum, gold, mercury, thallium, bismuth, or polonium; and X may be an anion selected from any one of iodide, bromide, chloride, astatide, thiocyanate, or acetate.

A composite transport layer of the second type of perovskite solar cell of the present disclosure has the following features:
1. The simple formation of openings during the coating of nanoparticles addresses the issue of excessively dense inorganic oxide layer structures, eliminates the influence of the thickness of the transition layer and buffer layer on electron tunneling, and reduces non-radiative recombination at the interface between the perovskite light-absorbing layer and the hole transport layer without impairing charge carrier transport.
2. Inorganic nanocrystals are prone to aggregation during long-term use due to surface defect-induced charge imbalance, which, once aggregation occurs, can negatively affect the stability of the material. However, the adhesive and dispersive effects of the coupling agent can avoid such a phenomenon, thereby enhancing the stability of the material and the device.
3. Since a large number of disordered dangling bonds exist on the surface of inorganic interfaces, the use of the coupling agent can also passivate these surface dangling bonds, thereby suppressing photocatalytic reactions between the inorganic material and the perovskite interface, and further enhancing stability.

As shown in FIG. 1, the present disclosure also discloses a method for preparing the first type of perovskite solar cell, comprising:

Operation 1-1, cleaning and ultraviolet ozone treatment may be performed on the transparent conductive layer 5.

In some embodiments, the cleaning may include using cleaning agents and various solvents to clean the transparent conductive layer 5. For example, the cleaning may be performed using surfactants such as dishwashing detergent, as well as deionized water and organic solvents such as acetone and isopropanol.

The ultraviolet ozone treatment refers to a manner for cleaning the surface of the transparent conductive layer 5. In some embodiments, the ultraviolet ozone treatment enables the photochemical oxidation of organic contaminants on the surface of the transparent conductive layer 5, thereby removing carbon-based impurities and improving surface properties, such as enhancing wettability and adhesion strength.

Operation 1-2, the transition layer 1 may be prepared on the transparent conductive layer 5 in a vapor phase manner or a liquid phase manner. The vapor phase manner refers to preparing the transition layer 1 using any one of an atomic layer deposition (ALD) device, a chemical vapor deposition (CVD) device, a magnetron sputtering device, an electron-beam evaporation device, or a thermal evaporation device, and the liquid phase manner refers to preparing the transition layer 1 by any one of a solution mixing manner, a hydrothermal manner, a chemical bath deposition (CBD) manner, or an in-situ doping manner.

In some embodiments, the liquid phase manner also includes manners such as a solution combustion manner, in which the transition layer 1 is prepared by applying a solution onto the transparent conductive layer 5 and combusting at a high temperature to remove the solution. Parameters such as a type of solution, a combustion time, and a combustion temperature of the solution combustion manner may be determined according to the actual application scenarios and needs.

Operation 1-3, the hole transport layer 2 may be prepared on the transition layer 1 using any one of the ALD device, the CVD device, the magnetron sputtering device, the electron-beam evaporation device, or the thermal evaporation device, or the hole transport layer 2 may be prepared by any one of blade coating, slot-die coating, or spray coating.

Operation 1-4, the buffer layer 3 may be prepared on the hole transport layer 2 in the vapor phase manner or the liquid phase manner. The vapor phase manner refers to preparing the buffer layer 3 using any one of the ALD device, the CVD device, the magnetron sputtering device, the electron-beam evaporation device, or the thermal evaporation device, and the liquid phase manner refers to preparing the buffer layer 3 by any one of the solution mixing manner, the hydrothermal manner, the CBD manner, or the in-situ doping manner.

In some embodiments, the buffer layer 3 may also be prepared in the solution combustion manner.

Operation 1-5, the perovskite light-absorbing layer 6, the electron transport layer 7, and the back electrode 8 may be sequentially prepared on the buffer layer 3 until preparation of the perovskite solar cell is completed.

In some embodiments, the perovskite light-absorbing layer 6 may be prepared in a one-step solution manner. The one-step solution manner refers to dissolving precursor materials that form a perovskite material in a solvent to form a homogeneous solution. The solution may then be coated directly onto the buffer layer 3. After coating, the solvent may be removed, and the perovskite light-absorbing layer may be crystallized directly on the buffer layer 3.

As shown in FIG. 2, the present disclosure also discloses a method for preparing the second type of perovskite solar cell, comprising:

Operation 2-1, cleaning and ultraviolet ozone treatment may be performed on the transparent conductive layer 5.

Operation 2-2: a first composite precursor solution may be obtained by mixing a coupling agent with a material solution for preparing the transition layer 1, ultraviolet illumination treatment or high-temperature treatment may be performed on the first composite precursor solution, and then the treated first composite precursor solution may be coated on the transparent conductive layer 5, and the treated first composite precursor solution on the transparent conductive layer may be annealed and dried to obtain the array transition layer 1.

The first composite precursor solution refers to a mixed solution for preparing the array transition layer 1. In some embodiments, the first composite precursor solution may be a nanoparticle suspension, and the first composite precursor solution may include nanoparticles of an inorganic compound, a coupling agent, and a solvent.

Operation 2-3, the hole transport layer 2 may be prepared on the transition layer 1 using any one of the ALD device, the CVD device, the magnetron sputtering device, the electron-beam evaporation device, or the thermal evaporation device, or the hole transport layer 2 may be prepared by any one of the blade coating, the slot-die coating, or the spray coating.

Operation 2-4, the buffer layer 3 may be prepared on the hole transport layer 2 in the vapor phase manner or the liquid phase manner. The vapor phase manner refers to preparing the buffer layer 3 using any one of the ALD device, the CVD device, the magnetron sputtering device, the electron-beam evaporation device, or the thermal evaporation device, and the liquid phase manner refers to preparing the buffer layer 3 by any one of the solution mixing manner, the hydrothermal manner, the chemical bath deposition (CBD) manner, or the in-situ doping manner.

Operation 2-5, the perovskite light-absorbing layer 6, the electron transport layer 7, and the back electrode 8 may be sequentially prepared on the buffer layer 3 until preparation of the perovskite solar cell is completed.

A detailed description of operation 2-1 to operation 2-5 can be found in the related descriptions of operation 1-1 to operation 1-5.

As shown in FIG. 3, the present disclosure also discloses a method for preparing the second type of perovskite solar cell, comprising:

Operation 3-1: cleaning and ultraviolet ozone treatment may be performed on the transparent conductive layer 5.

Operation 3-2, the transition layer 1 may be prepared on the transparent conductive layer 5 in the vapor phase manner or the liquid phase manner. The vapor phase manner refers to preparing the transition layer 1 using any one of the ALD device, the CVD device, the magnetron sputtering device, the electron-beam evaporation device, or the thermal evaporation device, and the liquid phase manner refers to preparing the transition layer 1 by any one of the solution mixing manner, the hydrothermal manner, the CBD manner, or the in-situ doping manner.

Operation 3-3, the hole transport layer 2 may be prepared on the transition layer 1 using any one of the ALD device, the CVD device, the magnetron sputtering device, the electron-beam evaporation device, or the thermal evaporation device, or the hole transport layer 2 may be prepared by any one of the blade coating, the slot-die coating, or the spray coating.

Operation 3-4: a second composite precursor solution may be obtained by mixing a coupling agent with a material solution for preparing the buffer layer 3, ultraviolet illumination treatment or high-temperature treatment may be performed on the second composite precursor solution, and then the treated second composite precursor solution may be coated on the hole transport layer 2, and the treated second composite precursor solution on the hole transport layer 2 may be annealed and dried to obtain the array buffer layer 3.

The second composite precursor solution refers to a mixed solution used to prepare the array buffer layer 3. In some embodiments, the second composite precursor solution may be a nanoparticle suspension, and the second composite precursor solution may include nanoparticles of an inorganic compound, a coupling agent, and a solvent.

Operation 3-5, the perovskite light-absorbing layer 6, the electron transport layer 7, and the back electrode 8 may be sequentially prepared on the buffer layer 3 until preparation of the perovskite solar cell is completed.

A detailed description of operation 3-1 to operation 3-5 can be found in the related descriptions of operation 1-1 to operation 1-5.

Referring to FIG. 4, the present disclosure also discloses a method for preparing the second type of perovskite solar cell, comprising:
Operation A: cleaning and ultraviolet ozone treatment may be performed on the transparent conductive layer 5.
Operation B: the first composite precursor solution may be obtained by mixing the coupling agent with the material solution for preparing the transition layer 1, and the ultraviolet illumination treatment or high-temperature treatment may be performed on the first composite precursor solution, and then the treated first composite precursor solution may be coated on the transparent conductive layer 5, and the treated first composite precursor solution on the transparent conductive layer 5 may be annealed and dried to obtain the array transition layer 1.
Operation C: the hole transport layer 2 may be prepared on the transition layer 1 using any one of the ALD device, the CVD device, the magnetron sputtering device, the electron-beam evaporation device, or the thermal evaporation device, or the hole transport layer 2 may be prepared by any one of the blade coating, the slot-die coating, or the spray coating.
Operation D: the second composite precursor solution may be obtained by mixing the coupling agent with the material solution for preparing the buffer layer 3, the ultraviolet illumination treatment or high-temperature treatment may be performed on the second composite precursor solution, and then the treated second composite precursor solution may be coated on the hole transport layer 2, and the treated second composite precursor solution on the hole transport layer 2 may be annealed and dried to obtain the array buffer layer 3.
Operation E: the perovskite light-absorbing layer 6, the electron transport layer 7, and the back electrode 8 may be sequentially prepared on the buffer layer 3 until preparation of the perovskite solar cell is completed.

A detailed description of Operation A, Operation C, and Operation E can be found in the related descriptions of Operation 1-1 to Operation 1-5. A detailed description of Operation B can be found in the related descriptions of Operation 2-2. A detailed description of Operation D can be found in the related descriptions of Operation 3-4.

In some embodiments, a condition of the ultraviolet illumination treatment may include a light wavelength in a range of 265 nm to 365 nm and an illumination treatment duration in a range of 5 min to 60 min. A condition of the high-temperature treatment may include a heating temperature in a range of 50° C. to 100° C. and a heating duration in a range of 5 min to 60 min.

In some embodiments, the light wavelength may also be one of 265 nm, 270 nm, 280 nm, 290 nm, 300 nm, 310 nm, 320 nm, 330 nm, 340 nm, 350 nm, 360 nm, or 365 nm; and the illumination treatment duration may also be one of 5 min, 10 min, 15 min, 20 min, 25 min, 30 min, 35 min, 40 min, 45 min, 50 min, 55 min, or 60 min.

In some embodiments, the heating temperature may also be one of 50° C., 55° C., 60° C., 65° C., 70° C., 75° C., 80° C., 85° C., 90° C., 95° C., or 100° C.; and the heating duration may also be one of 5 min, 10 min, 15 min, 20 min, 25 min, 30 min, 35 min, 40 min, 45 min, 50 min, 55 min, or 60 min.

In the present disclosure, during a coating and film-forming process, the difference in wettability between the nanoparticles used for preparing the transition layer and/or the buffer layer and a portion of the crosslinked coupling agent is utilized to form a plurality of array molecular groups containing the coupling agent that are continuously and discretely arranged and a plurality of openings separating two adjacent array molecular groups among the plurality of array molecular groups. As a result, an “array-like” transition layer and/or buffer layer containing the coupling agent can be obtained.

The structure of the perovskite solar cell disclosed in the present disclosure and a method for preparing the perovskite solar cell are further described below by way of specific embodiments.

### Embodiment 1

Referring to FIG. 1, an embodiment of a method for preparing a first type of perovskite solar cell according to the present disclosure is disclosed, comprising:

Operation 11: a glass of the fluorine-doped tin oxide (FTO) transparent conductive layer 5 was sequentially cleaned by ultrasonic treatment for 30 min each in dishwashing detergent, deionized water, acetone, and isopropanol, and then was dried with nitrogen (N₂), and was subjected to ultraviolet ozone treatment for 10 min.

Operation 12, the transition layer 1 with a thickness of 0.2 nm to 30 nm was prepared on the FTO transparent conductive layer 5 using a magnetron sputtering device, and a preparation material of the transition layer 1 has a chemical formula of Ni_{0.15}Al_{0.05}Sn_{0.8}O_{1.825}.

Operation 13: the nickel oxide hole transport layer 2 with a thickness of 1 nm to 100 nm was prepared by spin-coating a 0.15 M nickel acetylacetonate ethanol solution onto the transition layer 1 at 4000 rpm for 30 s, and subjected to combustion at 400° C. for 30 min.

Operation 14, the buffer layer 3 was prepared in a solution combustion manner, and a preparation material of the buffer layer 3 has a chemical formula of NiN_{0.3}O_{0.7}. A solution was prepared by dissolving 29 mg of nickel (II) nitrate hexahydrate (Ni(NO₃)₂·6H₂O) and 3 mg of urea in 1 ml of deionized water, after stirring, the solution was spray-coated onto the nickel oxide hole transport layer 2 to form the buffer layer 3 with a thickness of 0.2 nm to 50 nm, and then the buffer layer 3 was then heated at 400° C. for 30 min under a N₂ atmosphere, and was heated at 200° C. for 10 min in air.

Operation 15: the perovskite light-absorbing layer 6 was prepared on the buffer layer 3 in a one-step solution manner.

Operation 16: the electron transport layer 7 (PCBM) and a blocking layer (BCP) were coated sequentially on the perovskite light-absorbing layer 6, where PCBM represents [6,6]-phenyl-C61-butyric acid methyl ester, and BCP represents 2,9-dimethyl-4,7-diphenyl-1,10-phenanthroline.

Operation 17: the back electrode 8 (silver, Ag) was prepared on the electron transport layer 7 and the blocking layer until preparation of the perovskite solar cell was completed.

### Embodiment 2

Referring to FIG. 1, an embodiment of a method for preparing a first type of perovskite solar cell of the present disclosure is disclosed, comprising:

Operation 21: a glass of the FTO transparent conductive layer 5 was sequentially cleaned by ultrasonic treatment for 30 min each in dishwashing detergent, deionized water, acetone, and isopropanol, and then was dried with N₂, and was subjected to ultraviolet ozone treatment for 10 min.

Operation 22, the transition layer 1 was prepared on the FTO transparent conductive layer 5 in a mixing solution manner, and a preparation material of the transition layer 1 has the chemical formula of Cu_{0.05}Al_{0.2}Sn_{0.75}O_{1.85}. A solution was prepared by dissolving 1.4 mg of copper(II) chloride (CuCl₂), 5.4 mg of aluminum chloride (AlCl₃), and 28.5 mg of tin (II) chloride (SnCl₂) in 1 ml of deionized water, and after stirring, the solution was set aside for later use. Then the transition layer 1 with a thickness of 0.2 nm to 50 nm was prepared on the FTO transparent conductive layer 5 by blade coating using the solution, and then the coated transition layer 1 was heated at 500° C. for 1 h in air to obtain the desired transition layer 1.

Operation 23: the CuₓO hole transport layer 2 with a thickness of 1 nm to 100 nm was prepared on the transition layer 1 using a magnetron sputtering device.

Operation 24: the buffer layer 3 was prepared on the CuₓO hole transport layer 2 using the magnetron sputtering device, and a preparation material of the buffer layer 3 has a chemical formula of Cu_{0.4}Al_{0.6}O_{1.1}.

Operation 25: the perovskite light-absorbing layer 6 was prepared on the buffer layer 3 in a one-step solution manner.

Operation 26: the electron transport layer 7 (C60) and a blocking layer (acetylacetonate zirconium) were sequentially coated on the perovskite light-absorbing layer 6, where C60 represents fullerene C60.

Operation 27: the back electrode 8 (Ag) was prepared on the electron transport layer 7 and the blocking layer until preparation of the perovskite solar cell was completed.

### Embodiment 3

Referring to FIG. 1, an embodiment of a third method for preparing a first type of perovskite solar cell of the present disclosure is disclosed, comprising:

Operation 31: a glass of the FTO transparent conductive layer 5 was sequentially cleaned by ultrasonic treatment for 30 min each in dishwashing detergent, deionized water, acetone, and isopropanol, and then was dried with N₂, and was subjected to ultraviolet ozone treatment for 10 min.

Operation 32: a hydrochloric acid solution containing 0.1 M nickel (II) chloride (NiCl₂) and 0.1 M aluminium chlorid (AlCl₃) was prepared. With iron (Fe) serving as a catalyst, the FTO transparent conductive layer 5 was soaked and treated using the solution for 10 min to 30 min, and the treated transparent conductive layer 5 was heated in air at 500° C. for 30 min to prepare the in-situ formed transition layer 1 on the FTO transparent conductive layer 5, and the transition layer 1 has a chemical formula of Ni_{0.9}Al_{0.1}Sn_{0.8}O_{1.9}.

Operation 33: the nickel oxide hole transport layer 2 was prepared by spin-coating a 0.15 M nickel acetylacetonate ethanol solution onto the transition layer 1 at 4000 rpm for 30 s, and subjected to combustion at 400° C. for 30 min.

Operation 34, the buffer layer 3 was prepared on the hole transport layer 2 using a CVD device under ammonia (NH₃) and oxygen (O₂) atmospheres, respectively, and a preparation material of the buffer layer 3 has a chemical formula of Ni_{0.9}Al_{0.1}N_{0.1}O_{0.9}.

Operation 35: the perovskite light-absorbing layer 6 was prepared on the buffer layer 3 in a one-step solution manner.

Operation 36: the electron transport layer 7 (C60) and the electron transport layer 7 (stannic oxide (SnO₂)) were sequentially coated on the perovskite light-absorbing layer 6.

Operation 37: the back electrode 8 (copper) was prepared on the electron transport layer 7 until preparation of the perovskite solar cell was completed.

### Embodiment 4

Referring to FIG. 1, an embodiment of a method for preparing a first type of perovskite solar cell of the present disclosure is disclosed, comprising:

Operation 41: a glass of the FTO transparent conductive layer 5 was sequentially cleaned by ultrasonic treatment for 30 min each in dishwashing detergent, deionized water, acetone, and isopropanol, and then was dried with N₂, and was subjected to ultraviolet ozone treatment for 10 min.

Operation 42, the transition layer 1 was prepared on the FTO transparent conductive layer 5 using a CVD device, and a preparation material of the transition layer 1 has a chemical formula of Cu_{0.05}Al_{0.2}Sn_{0.75}O_{1.85}.

Operation 43: the CuSCN hole transport layer 2 was prepared on the transition layer 1 using a solution manner.

Operation 44: a nanocrystalline mixture of copper(I) oxide (Cu₂O) and aluminum oxide (Al₂O₃) was deposited on the CuSCN hole transport layer 2 by blade coating, and the buffer layer 3 (Cu_{0.5}Al_{0.5}O) was prepared.

Operation 45: the perovskite light-absorbing layer 6 was prepared on the buffer layer 3 in a one-step solution manner.

Operation 46: the electron transport layer 7 (SnO₂) was coated on the perovskite light-absorbing layer 6.

Operation 47: the back electrode 8 (Ag) was prepared on the electron transport layer 7 until preparation of the perovskite solar cell was completed.

A composite transport layer of the first type of perovskite solar cell of the present disclosure has the following features:
1. Conventional transparent conductive layers, such as the FTO transparent conductive layer, are typically n-type doped. In the present disclosure, a gradient-doped transition layer is introduced between the transparent conductive layer and the hole transport layer by incorporating p-type dopants, such as Al, B, and Si, into the transition layer, which creates a doping concentration gradient and energy-level alignment. In addition, the buffer layer replaces organic materials with nitrogen-containing inorganic compounds, which exhibits superior photothermal stability and effectively passivates surface defects of the hole transport layer, thereby enhancing the stability of a second interface between the hole transport layer and the perovskite light-absorbing layer.
2. The perovskite solar cell of the present disclosure greatly improves the photo-stability of the perovskite solar cell due to the composite transport layer. For example, when NiOₓ is used as the hole transport layer, nickel (Ni) mainly exists in the forms of Ni²⁺, Ni³⁺, and a small amount of Ni⁴⁺. While Ni³⁺ can enhance charge carrier transport, the presence of Ni³⁺ and higher-valence nickel species can also lead to photocatalytic activity of Ni, thereby affecting the photo-stability of the perovskite solar cell. The transition layer disclosed in the present disclosure enables a gradual transition from a hole transport material to a perovskite material, while controlling the proportion of Ni³⁺ and higher-valence Ni species within the transition layer, thereby significantly improving the photo-stability of the perovskite solar cell.

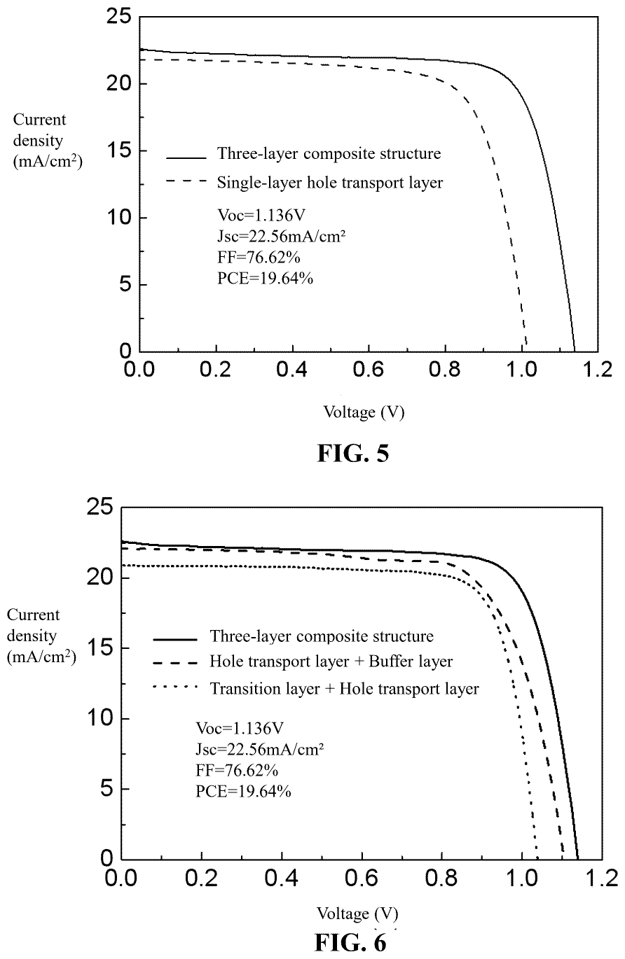

FIG. 5 is a schematic diagram illustrating a comparison of power conversion efficiency curves of a perovskite solar cell prepared in Embodiment 1 of the present disclosure and a perovskite solar cell prepared in Comparative Example 1. As shown in FIG. 5, the power conversion efficiency curve of the perovskite solar cell (i.e., a three-layer composite structure) prepared in Embodiment 1 of the present disclosure, and the power conversion efficiency curve of an existing perovskite solar cell (i.e., a single-layer hole transport layer) including a single-layer hole transport layer prepared in Comparative Example 1 are shown and compared. As can be seen from FIG. 5, the open-circuit voltage of a perovskite solar cell comprising a composite transport layer proposed in the present disclosure is significantly improved. The open-circuit voltage of the single-layer hole transport layer reaches 1.014 V, whereas the open-circuit voltage of the three-layer composite structure reaches 1.136 V.

FIG. 6 is a schematic diagram illustrating a comparison of power conversion efficiency curves of a perovskite solar cell prepared in Embodiment 1 of the present disclosure and perovskite solar cells prepared in Comparative Examples 2 and 3. As shown in FIG. 6, the power conversion efficiency curve of a perovskite solar cell comprising a transition layer and a hole transport layer (i.e., transition layer+hole transport layer) in Comparative Example 2, and the power conversion curve of a perovskite solar cell comprising a hole transport layer and a buffer layer (i.e., hole transport layer+buffer layer) in Comparative Example 3 are shown and compared. As can be seen from FIG. 6, compared to the perovskite solar cell prepared in Comparative Example 2, the short-circuit current density (Jsc) and open-circuit voltage (Voc) of the perovskite solar cell prepared in Embodiment 1 are significantly improved, and compared to the perovskite solar cell prepared in Comparative Example 3, the fill factor (FF) of the perovskite solar cell prepared in Embodiment 1 is significantly improved, and the open-circuit voltage (Voc) is further increased, and the power conversion efficiency reaches 19.64%.

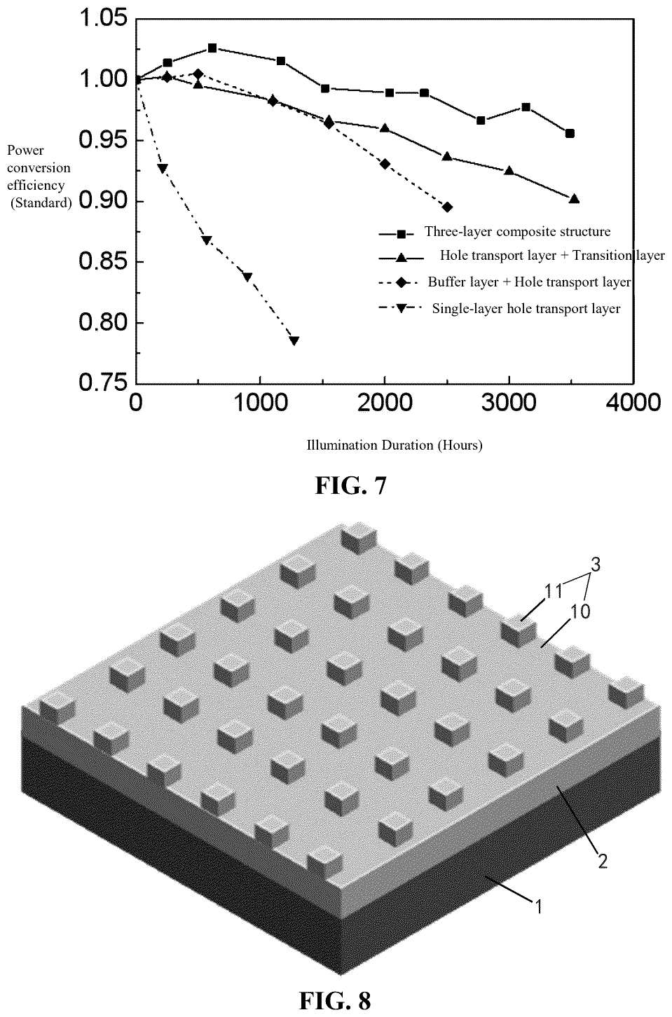

FIG. 7 is a schematic diagram illustrating a comparison of aging experiment curves of a perovskite solar cell prepared in Embodiment 1 of the present disclosure and perovskite solar cells prepared in Comparative Embodiments 1 to 3. As shown in FIG. 7, the aging experiment curve of the perovskite solar cell (i.e., a three-layer composite structure) prepared in Embodiment 1 of the present disclosure, the aging experiment curve of the perovskite solar cell prepared in Comparative Example 1 (i.e., a single-layer hole transport layer), the aging experiment curve of the perovskite solar cell prepared in Comparative Example 2 (i.e., a two-layer structure including a transition layer and a hole transport layer), and the aging experiment curve of the perovskite solar cell prepared in Comparative Example 3 (i.e., a two-layer structure including a hole transport layer and a buffer layer) are shown and compared. As can be seen from FIG. 7, both the perovskite solar cells prepared in Comparative Example 2 and Comparative Example 3 exhibit improved photo-aging stability compared to the perovskite solar cell prepared in Comparative Example 1. Besides, the perovskite solar cell prepared in Embodiment 1 of the present disclosure exhibits less than 5% degradation after 3,500 hours of photo-aging, which is significantly superior to the test results of the perovskite solar cells prepared in Comparative Examples 1 to 3.

### Embodiment 5

Referring to FIG. 2, an embodiment of a method for preparing a second type of perovskite solar cell is disclosed, comprising:

Operation 51: a glass of the FTO transparent conductive layer 5 was sequentially cleaned by ultrasonic treatment for 30 min each in dishwashing detergent, deionized water, acetone, and isopropanol, and then was dried with N₂, and was subjected to ultraviolet ozone treatment for 10 min.

Operation 52: a solution was prepared by mixing 3-Aminopropyltriethoxysilane with a nanoparticle suspension of Al₂O₃ and SnO₂ (10 wt %, 100 nm) in isopropyl alcohol (IPA) at a volume ratio of 1%. After stirring thoroughly, the solution was irradiated under a 365 nm ultraviolet lamp for 10 min and set aside for later use. The resulting suspension was coated onto the FTO transparent conductive layer 5 by blade coating. After a wet film (a liquid layer formed on the surface of the FTO transparent conductive layer 5 after coating) was heated and annealed, the array transition layer 1 with openings 10 was formed.

Operation 53: the nickel oxide hole transport layer 2 with a thickness of 1 nm to 100 nm was prepared by spin-coating a 0.15 M nickel acetylacetonate ethanol solution onto the transition layer 1 at 4000 rpm for 30 s, and subjected to combustion at 400° C. for 30 min.

Operation 54, the buffer layer 3 was prepared in a solution combustion manner, and a preparation material of the buffer layer 3 has a chemical formula of NiN_{0.3}O_{0.7}. A solution was prepared by dissolving 29 mg NiNO₃.6H₂O and 3 mg of urea solution in 1 ml of deionized water, after stirring, the solution was set aside for later use. The buffer layer 3 with a thickness of 0.2 mm to 50 mm was prepared on the nickel oxide hole transport layer 2 by spray coating using the solution, and the buffer layer 3 was heated under the N₂ atmosphere at 400° C. for 300 min, and was heated in air at 200° C. for 10 min.

Operation 55: the perovskite light-absorbing layer 6 was prepared on the buffer layer 3 in a one-step solution manner.

Operation 56: the electron transport layer 7 (PCBM) and a blocking layer (BCP) were sequentially coated on the perovskite light-absorbing layer 6.

Operation 57: the back electrode 8 (Ag) was prepared on the electron transport layer 7 and the blocking layer until preparation of the perovskite solar cell was completed.

### Embodiment 6

Referring to FIG. 3 and FIG. 8, an embodiment of a method for preparing a second type of perovskite solar cell of the present disclosure is disclosed, comprising:

Operation 61: a glass of the FTO transparent conductive layer 5 was sequentially cleaned by ultrasonic treatment for 30 min each in dishwashing detergent, deionized water, acetone, and isopropanol, and then was dried with N₂, and was subjected to ultraviolet ozone treatment for 10 min.

Operation 62: the transition layer 1 with a thickness of 0.2 nm to 30 nm was prepared on the FTO transparent conductive layer 5 in a mixing solution manner, and a preparation material of the transition layer 1 has a chemical formula of Cu_{0.05}Al_{0.2}Sn_{0.75}O_{1.85}. A solution was prepared by dissolving 1.4 mg of CuCl₂, 5.4 mg of AlCl₃, and 28.5 mg of SnCl₂ in 1 ml of deionized water, after stirring, the solution was set aside for later user. The transition layer 1 was prepared on the FTO transparent conductive layer 5 by blade coating using the solution, and the transition layer 1 was heated in air at 500° C. for 1 h to obtain the desired transition layer 1.

Operation 63: the CuₓO hole transport layer 2 with a thickness of 1 nm to 100 nm was prepared on the transition layer 1 using a magnetron sputtering device.

Operation 64: a solution was prepared by mixing vinyltriethoxysilane and a nanoparticle solution of CuₓO and silicon dioxide (SiO₂) (10 wt %, 80 nm) in deionized water at a volume ratio of 1%. After stirring, the resulting solution was heated and stirred at 80 to 100° C. for 30 min, then set aside for later use. The prepared suspension was then coated onto the CuₓO hole transport layer 2 by blade coating, and after coating, the CuₓO hole transport layer 2 was annealed to form the array buffer layer 3 with openings 10.

Operation 65: the perovskite light-absorbing layer 6 was prepared on the buffer layer 3 in a one-step solution manner.

Operation 66: the electron transport layer 7 (C60) and a blocking layer (zirconium acetylacetonate) were sequentially coated on the perovskite light-absorbing layer 6.

Operation 67: the back electrode 8 (Ag) was prepared on the electron transport layer 7 and the blocking layer until preparation of the perovskite solar cell was completed.

A composite transport layer of the second type of perovskite solar cell of the present disclosure has the following features:
1. Conventional transparent conductive layers, such as the FTO transparent conductive layer, are typically n-type doped. In the present disclosure, a gradient-doped transition layer is introduced between the transparent conductive layer and the hole transport layer by incorporating p-type dopants, such as Al, B, and Si, into the transition layer, which creates a doping concentration gradient and energy-level alignment. In addition, the buffer layer replaces organic materials with nitrogen-containing inorganic compounds, which exhibit superior photothermal stability and effectively passivate surface defects of the hole transport layer, thereby enhancing the stability of a second interface between the hole transport layer and the perovskite light-absorbing layer.
2. The perovskite solar cell of the present disclosure greatly improves the photo-stability of the perovskite solar cell due to the composite transport layer. For example, when NiOₓ is used as the hole transport layer, nickel (Ni) mainly exists in the forms of Ni²⁺, Ni³⁺, and a small amount of Ni⁴⁺. While Ni³⁺ can enhance charge carrier transport, the presence of Ni³⁺ and higher-valence nickel species can also lead to photocatalytic activity of Ni, thereby affecting the photo-stability of the perovskite solar cell. The transition layer disclosed in the present disclosure enables a gradual transition from a hole transport material to a perovskite material, while controlling the proportion of Ni³⁺ and higher-valence Ni species within the transition layer, thereby significantly improving the photo-stability of the perovskite solar cell.
3. Simple formation of openings during the coating of nanoparticles addresses the issue of excessively dense inorganic oxide layer structures, eliminates the influence of the thickness of the transition layer and buffer layer on electron tunneling, and reduces non-radiative recombination at the interface between the perovskite light-absorbing layer and the hole transport layer without impairing charge carrier transport.
4. Inorganic nanocrystals are prone to aggregation during long-term use due to surface defect-induced charge imbalance, which, once aggregation occurs, can negatively affect the stability of the material. However, the adhesive and dispersive effects of the coupling agent can avoid such a phenomenon, thereby enhancing the stability of the material and the device.
5. Since a large number of disordered dangling bonds exist on the surface of inorganic interfaces, the use of the coupling agent can also passivate these surface dangling bonds, thereby suppressing photocatalytic reactions between the inorganic material and the perovskite interface, and further enhancing stability.

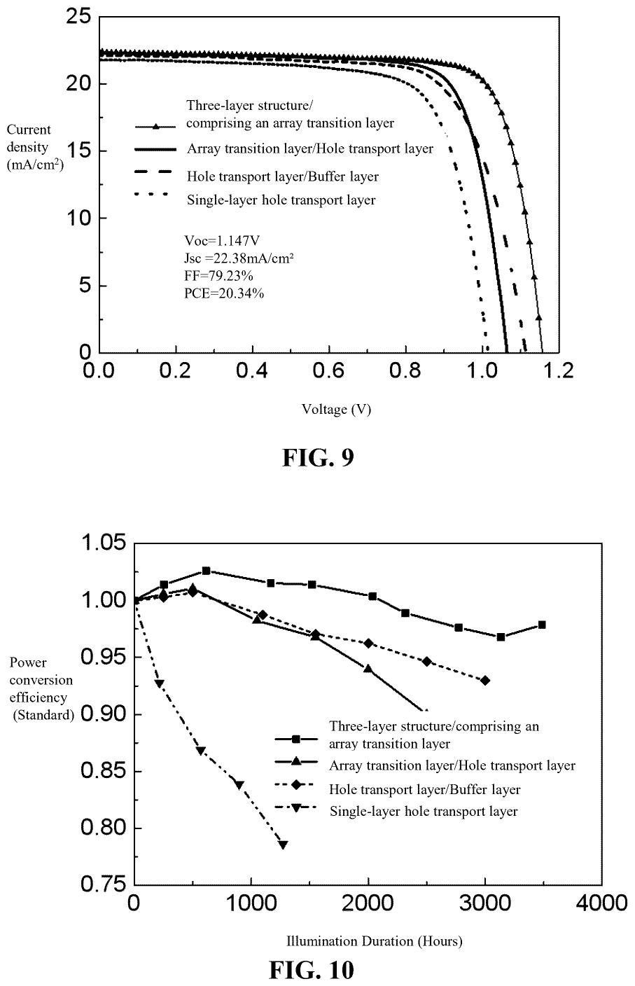

Referring to FIG. 9, a power conversion efficiency curve of a perovskite solar cell (i.e., three-layer structure/comprising an array transition layer) prepared in Embodiment 5 of the present disclosure, a power conversion efficiency curve of a perovskite solar cell including a single-layer hole transport layer (i.e., a single hole transport layer) prepared in Comparative Embodiment 1, a power conversion efficiency curve of a perovskite solar cell including an array transition layer and a hole transport layer (i.e., an array transition layer/hole transport layer) prepared in Comparative Embodiment 4, and a power conversion efficiency curve of a perovskite solar cell including a hole transport layer and a buffer layer (i.e., hole transport layer/buffer layer) prepared in Comparative Embodiment 3 are shown and compared. A difference between the perovskite solar cell prepared in Comparative Embodiment 4 and the perovskite solar cell prepared in Embodiment 6 is that the perovskite solar cell prepared in Comparative Embodiment 4 does not include a buffer layer. A difference between the perovskite solar cell prepared in Comparative Example 3 and the perovskite solar cell prepared in Embodiment 6 is that the perovskite solar cell prepared in Comparative Example 3 does not include a transition layer, and the buffer layer is not in the form of an array. As can be seen from FIG. 9, the open-circuit voltage (1.147 V) and the fill factor (79.23%) of the perovskite solar cell of a three-layer structure prepared in Embodiment 5 of the present disclosure are significantly improved compared to the perovskite solar cells prepared in Comparative Examples 1, 4, and 3. At the same time, as can be seen from a comparison of FIG. 9 and FIG. 5, the efficiency of the perovskite solar cell of a three-layer composite structure with an array structure is superior to the perovskite solar cell of the three-layer composite structure without the array structure. Specifically, the open-circuit voltage of the perovskite solar cell of a three-layer composite structure with an array structure is increased from 1.136 V to 1.147 V, the fill factor is increased from 76.62% to 79.23%, and the power conversion efficiency is increased from 19.64% to 20.34% (an increase of approximately 3.6%).

Referring to FIG. 10, a photo-aging curve of a perovskite solar cell (i.e., three-layer structure/comprising an array transition layer) prepared in Embodiment 5 of the present disclosure, a photo-aging curve of a perovskite solar cell including a single-layer hole transport layer (i.e., a single hole transport layer) prepared in Comparative Embodiment 1, a photo-aging curve of a perovskite solar cell including an array transition layer and a hole transport layer (i.e., an array transition layer/hole transport layer) prepared in Comparative Embodiment 4, and a photo-aging curve of a perovskite solar cell including a hole transport layer and a buffer layer (i.e., hole transport layer/buffer layer) prepared in Comparative Embodiment 3 are shown and compared. Compared to the perovskite solar cell prepared in Comparative Example 1, the photostability of the perovskite solar cells prepared in Comparative Examples 4 and 5 is significantly improved. However, the aging test result of the perovskite solar cell prepared in Embodiment 5 of the present disclosure is significantly better than the perovskite solar cells prepared in Comparative Examples 1, 4, and 3. The perovskite solar cell prepared in Embodiment 5 exhibits no degradation after 2000 hours of continuous illumination, and the degradation remains below 3% even after 3500 hours. At the same time, a comparison of FIG. 7 and FIG. 10 reveals that the photostability of the perovskite solar cell of a three-layer composite structure with an array structure is also superior to the perovskite solar cell of a three-layer composite structure without an array structure. After 3500 hours of illumination, the degradation is reduced from approximately 5% to less than 3%.

The basic concepts have been described above, and it is apparent to those skilled in the art that the foregoing detailed disclosure serves only as an example and does not constitute a limitation of the present disclosure. While not expressly stated herein, a person skilled in the art may make various modifications, improvements, and amendments to the present disclosure. Those types of modifications, improvements, and amendments are suggested in the present disclosure, so those types of modifications, improvements, and amendments remain within the spirit and scope of the exemplary embodiments of the present disclosure.

Similarly, it should be noted that to simplify the presentation of the present disclosure, and thereby aid in the understanding of one or more embodiments of the invention, the foregoing descriptions of embodiments of the present disclosure sometimes group multiple features together in a single embodiment, accompanying drawings, or in a description thereof. However, this method of disclosure does not imply that the objects of the present disclosure require more features than those mentioned in the claims. Rather, claimed subject matter may lie in less than all features of a single foregoing disclosed embodiment.

Finally, it should be understood that the embodiments described in the present disclosure are only used to illustrate the principles of the embodiments of the present disclosure. Other deformations may also fall within the scope of the present disclosure. As such, alternative configurations of embodiments of the present disclosure may be viewed as consistent with the teachings of the present disclosure as an example, not as a limitation. Correspondingly, the embodiments of the present disclosure are not limited to the embodiments expressly presented and described herein.

What is claimed is:

1. A composite transport layer, comprising a transition layer, a hole transport layer, and a buffer layer sequentially stacked along a light incident direction, wherein
a preparation material of the transition layer is NiₓA_{y}Si_{z}SnₘOₙ or CuₓA_{y}Si_{z}SnₘOₙ, x>0, y≥0, z≥0, m≥0, n>0, A is aluminum (Al) or boron (B), and the preparation material of the transition layer at least includes any one of A, silicon (Si), or tin (Sn);
a preparation material of the hole transport layer is any one of NiOₓ, CuₓO, or CuSCN; and
a preparation material of the buffer layer is NiₐE_{b}N_{c}O_{d} or CuₐE_{b}N_{c}O_{d}, a>0, b≥0, c>0, d≥0, and E is any one of Al, B, Si, zinc (Zn), cobalt (Co), or zirconium (Zr).

2. A composite transport layer, comprising a transition layer, a hole transport layer, and a buffer layer sequentially stacked along a light incident direction, wherein
a preparation material of the transition layer is NiₓA_{y}Si_{z}SnₘOₙ or CuₓA_{y}Si_{z}SnₘOₙ, x>0, y≥0, z≥0, m≥0, n>0, A is aluminum (Al) or boron (B), and the preparation material of the transition layer at least includes any one of A, Si, or Sn;
a preparation material of the hole transport layer is any one of NiOₓ, CuₓO, or CuSCN; and
a preparation material of the buffer layer is NiₐE_{b}N_{c}O_{d} or CuₐE_{b}N_{c}O_{d}, a>0, b≥0, c>0, d≥0, and E is any one of Al, B, Si, Zn, Co, or Zr;
the preparation material of the transition layer and/or the buffer layer is doped with a coupling agent to obtain a corresponding array transition layer and/or array buffer layer containing the coupling agent, a thin film prepared from the array transition layer and/or the array buffer layer doped with the coupling agent includes a plurality of array molecular groups containing the coupling agent that are discretely arranged and a plurality of openings separating two adjacent array molecular groups among the plurality of array molecular groups, and each of the plurality of opening communicates an upper surface and lower surface of the thin film in which it is located, respectively; and
the coupling agent is any one of a silane coupling agent, a titanate coupling agent, an aluminate coupling agent, a phosphate coupling agent, or a borate coupling agent.

3. The composite transport layer of claim 2, wherein an addition amount of the coupling agent is in a range of 0.5% to 5% of a volume of a nanoparticle suspension for preparing the transition layer and/or the buffer layer, and a concentration of the nanoparticle suspension is in a range of 0.1 wt. % to 10 wt. %.

4. The composite transport layer of claim 2, wherein a length of the opening is in a range of 10 nm to 200 nm.

5. The composite transport layer of claim 1, wherein a thickness of the transition layer is in a range of 0.2 nm to 30 nm, a thickness of the hole transport layer is in a range of 1 nm to 100 nm, and a thickness of the buffer layer is in a range of 0.2 nm to 50 nm.

6. A perovskite solar cell, comprising a transparent conductive layer, a perovskite light-absorbing layer, an electron transport layer, and a back electrode stacked sequentially, wherein the composite transport layer of claim 1 is arranged between the transparent conductive layer and the perovskite light-absorbing layer, a transition layer of the composite transport layer is in conformal contact with the transparent conductive layer, and a buffer layer of the composite transport layer is in conformal contact with the perovskite light-absorbing layer.

7. A perovskite solar cell, comprising a transparent conductive layer, a perovskite light-absorbing layer, an electron transport layer, and a back electrode stacked sequentially, wherein the composite transport layer of claim 2 is arranged between the transparent conductive layer and the perovskite light-absorbing layer, a transition layer of the composite transport layer is in conformal contact with the transparent conductive layer, and a buffer layer of the composite transport layer is in conformal contact with the perovskite light-absorbing layer.

8. A method for preparing the perovskite solar cell of claim 6, comprising:
operation 1-1, cleaning and performing ultraviolet ozone treatment on the transparent conductive layer;
operation 1-2, preparing the transition layer on the transparent conductive layer in a vapor phase manner or a liquid phase manner, wherein the vapor phase manner is to prepare the transition layer using any one of an atomic layer deposition (ALD) device, a chemical vapor deposition (CVD) device, a magnetron sputtering device, an electron-beam evaporation device, or a thermal evaporation device, and the liquid phase manner is to prepare the transition layer by any one of a solution mixing manner, a hydrothermal manner, a chemical bath deposition (CBD) manner, or an in-situ doping manner;
operation 1-3, preparing the hole transport layer on the transition layer using any one of the ALD device, the CVD device, the magnetron sputtering device, the electron-beam evaporation device, or the thermal evaporation device, or preparing the hole transport layer by any one of blade coating, slot-die coating, or spray coating;
operation 1-4, preparing the buffer layer on the hole transport layer in the vapor phase manner or the liquid phase manner, wherein the vapor phase manner is to prepare the buffer layer using any one of the ALD device, the CVD device, the magnetron sputtering device, the electron-beam evaporation device, or the thermal evaporation device, and the liquid phase manner is to prepare the buffer layer by any one of the solution mixing manner, the hydrothermal manner, the CBD manner, or the in-situ doping manner; and
operation 1-5, preparing the perovskite light-absorbing layer, the electron transport layer, and the back electrode on the buffer layer sequentially until preparation of the perovskite solar cell is completed.

9. A method for preparing the perovskite solar cell of claim 7, comprising:
operation 2-1, cleaning and performing ultraviolet ozone treatment on the transparent conductive layer;
operation 2-2, obtaining a first composite precursor solution by mixing the coupling agent with a material solution for preparing the transition layer, performing ultraviolet irradiation treatment or high-temperature treatment on the first composite precursor solution, and then coating the treated first composite precursor solution on the transparent conductive layer, and annealing and drying the treated first composite precursor solution on the transparent conductive layer to obtain an array transition layer;
operation 2-3, preparing the hole transport layer on the transition layer using any one of an atomic layer deposition (ALD) device, a chemical vapor deposition (CVD) device, a magnetron sputtering device, an electron-beam evaporation device, or a thermal evaporation device, or preparing the hole transport layer by any one of blade coating, slot-die coating, or spray coating;
operation 2-4, preparing the buffer layer on the hole transport layer in a vapor phase manner or a liquid phase manner, wherein the vapor phase manner is to prepare the buffer layer using any one of the ALD device, the CVD device, the magnetron sputtering device, the electron-beam evaporation device, or the thermal evaporation device, and the liquid phase manner is to prepare the buffer layer by any one of a solution mixing manner, a hydrothermal manner, a chemical bath deposition (CBD), or an in-situ doping manner; and
operation 2-5, preparing the perovskite light-absorbing layer, the electron transport layer, and the back electrode on the buffer layer sequentially until preparation of the perovskite solar cell is completed.

10. A method for preparing the perovskite solar cell of claim 7, comprising:
operation 3-1, cleaning and performing ultraviolet ozone treatment on the transparent conductive layer;
operation 3-2, preparing the transition layer on the transparent conductive layer in a vapor phase manner or a liquid phase manner, wherein the vapor phase manner is to prepare the transition layer using any one of an atomic layer deposition (ALD) device, a chemical vapor deposition (CVD) device, a magnetron sputtering device, an electron-beam evaporation device, or a thermal evaporation device, and the liquid phase manner is to prepare the transition layer by any one of a solution mixing manner, a hydrothermal manner, a chemical bath deposition (CBD), or an in-situ doping manner;
operation 3-3, preparing the hole transport layer on the transition layer using any one of the ALD device, the CVD device, the magnetron sputtering device, or the electron-beam evaporation device, and the thermal evaporation device, or preparing the hole transport layer on the transition layer by any one of blade coating, slot-die coating, or spray coating;
operation 3-4, obtaining a second composite precursor solution by mixing the coupling agent with a material solution for preparing the buffer layer, performing ultraviolet irradiation treatment or high-temperature treatment on the second composite precursor solution, and then coating the treated second composite precursor solution on the hole transport layer, and annealing and drying the treated second composite precursor solution on the hole transport layer to obtain an array buffer layer; and
operation 3-5, preparing the perovskite light-absorbing layer, the electron transport layer, and the back electrode on the buffer layer sequentially until preparation of the perovskite solar cell is completed.
